(19) United States
(12) Patent Application Publication
(10) Pub. No.: US 2020/0149635 A1
(43) Pub. Date: May 14, 2020

(54) HERMETIC GLASS-TO-METAL SEAL REINFORCED WITH A CERAMIC DISC TO PREVENT CRACK PROPAGATION

(71) Applicant: Stephen Vincent Rust, Ringwood, NJ (US)

(72) Inventor: Stephen Vincent Rust, Ringwood, NJ (US)

(21) Appl. No.: 16/186,800

(22) Filed: Nov. 12, 2018

(51) Int. Cl. F16J 15/10; H05K 5/06

(52) U.S. Cl. CPC F16J 15/102; H05K 5/069

(57) ABSTRACT

A glass-to-metal seal assembly for electrical components. The glass-to-metal seal assembly provides ceramic washers that sandwiches the glass portion of the glass-to-metal seals. The ceramic washer encases the glass seal, thereby reinforcing the glass surface against crack propagation and the formation of a fragile glass meniscus at the interface of the glass seal and the encased electrical component. The ceramic washers may have a coefficient of thermal expansion that closely matches the coefficient of thermal expansion all of the other components of the assembly.

### BACKGROUND OF THE INVENTION

The present invention relates to hermetic seals and, more particularly, to a glass-to-metal hermetic seal reinforced with a ceramic disc or washer to prevent crack propagation.

Glass-to-metal seals are a very important element of the construction of vacuum tubes, electric discharge tubes, glass encapsulated semiconductor diodes, and metal or ceramic packages of electrical components. Glass seals, however, are prone to fail when exposed to mechanical and thermal stresses or when the pin is subjected to bending. Glass-to-metal seals typically include a body of metal having a through hole that is filled with molten glass, which upon cooling solidifies forming hermetic seals within the void with any compatible object within the through hole. In the field of electronics, the object is typically a pin, that the body of glass forms a seal and interfaces with.

The resulting glass seal extends between opposing ends within said through hole. The surface of the glass seal at these ends are exposed and so prone to cracking. Furthermore, during cooling, the glass seal tends to be susceptible to excessive wicking up of the metal components, forming a fragile glass meniscus at the interface of the glass seal and the encased electrical pin, as well as the interface of the glass seal and the through hole. In other words, at the interface between the first or outer diameter (ODP) of the pin and the second or inner diameter (IDG) of the glass encasement, and at the outer diameter (ODG) of the glass seal and the inner diameter (IDM) of the metal through hole.

As mentioned above, this meniscus is prone to chipping which can expose base material of the pin. This can lead to corrosion of the pin since this exposed area will no longer be protected by nickel or other plating which can compromise the integrity of the pin. Furthermore, upon the formation of the glass-to-metal seal, specifically when the glass is in a molten state, the center pin is prone to shifting radially creating a condition whereby the pin is not concentric within the through hole. This can lead to electrical performance issues such as reduction of the dielectric withstanding voltage, reduction of insulation resistance, and changes in impedance.

As can be seen, there is a need for a glass-to-metal hermetic seal reinforced with a ceramic disc to prevent crack propagation at said opposing ends through providing a barrier at the glass surface. Upon softening and melting of the sealing glass, the glass effectively wets and bonds to the metal body, the pin, and the ceramic disc, encasing the glass from the external environment, thereby reinforcing the glass body against crack propagation from stresses that the glass may experience. Specifically, stresses initiating in the glass are transferred to the ceramic disc, which being a tougher material, resists cracking. Therefore, any cracks that may originate at the IDP and IDM-ODG interfaces of the hermetic seal are terminated when they reach the glass/ceramic interface. Accordingly, the present invention also prevents the formation of the fragile glass meniscuses that typically form. The rigid ceramic disc also keeps the pin concentric within the through hole.

### SUMMARY OF THE INVENTION

In one aspect of the present invention, a glass-to-metal seal assembly for electrical components providing one or more glass-to-metal seals wherein a ceramic washer sandwiches the opposing ends of a glass portion of at least one glass-to-metal seal.

In another aspect of the present invention, the glass-to-metal seal assembly further includes a metal body providing a through hole for each glass-to-metal seal, each through hole filled with the glass portion; the metal body providing a first body surface and an opposing body second surface; the glass portion terminating at opposing first and second glass surfaces; and each first and second glass surface abuts a first ceramic surface of an operatively associated ceramic washer.

These and other features, aspects and advantages of the present invention will become better understood with reference to the following drawings, description and claims.

### BRIEF DESCRIPTION OF THE DRAWINGS

FIG. 1 is a perspective view of an exemplary embodiment of the present invention, shown in use;

FIG. 2 is a detailed exploded perspective view of an exemplary embodiment of the present invention, taken along line 2-2 in FIG. 1;

FIG. 3 is a cross-sectional view of an exemplary embodiment of the present invention, taken along line 3-3 in FIG. 2;

FIG. 4 is a cross-sectional view of an alternative exemplary embodiment of the present invention taken alone a view similar to that of FIG. 3; and

FIG. 5 is a cross-sectional view of an alternative exemplary embodiment of the present invention taken alone a view similar to that of FIG. 3.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, an embodiment of the present invention provides a glass-to-metal seal assembly for electrical components. The glass-to-metal seal assembly provides ceramic washers that sandwiches the glass portion of the glass-to-metal seals. The ceramic washer encases the glass seal, thereby reinforcing the glass surface against crack propagation and the formation of a fragile glass meniscus at the interface of the glass seal and the encased pin., and at the interface of the glass seal and the through hole, and keeps the pin centered in the through hole. The ceramic washers may have a coefficient of thermal expansion that closely matches the coefficient of thermal expansion all of the other components of the assembly.

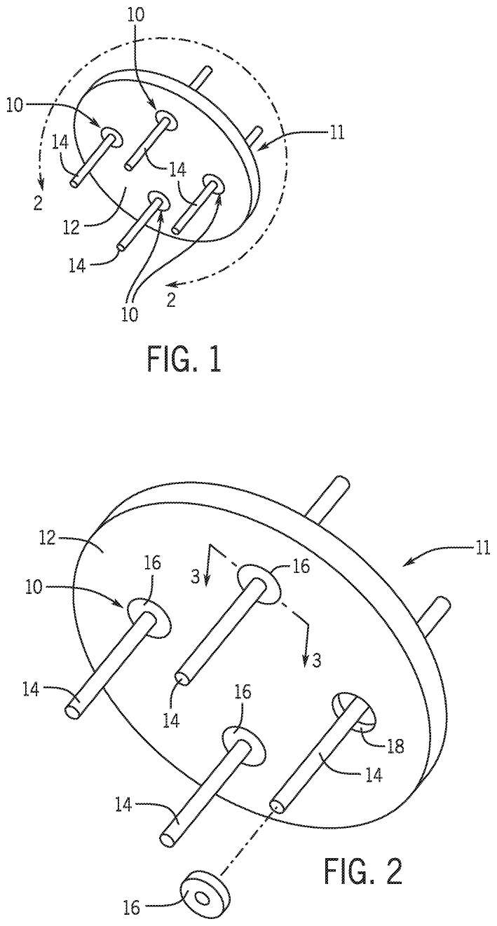

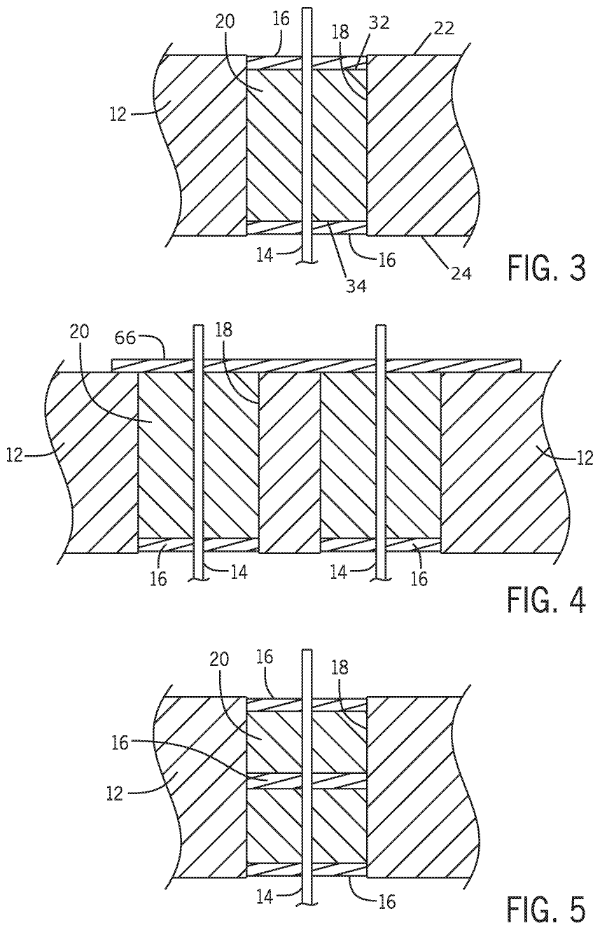

Referring to FIGS. 1 through 5, the present invention may include a system, method, and device for forming a hermetic glass-to-metal seal, particularly for electrical components.

The present invention may include a hermetic glass-to-metal reinforced seal 10 that may be configured in one or more glass-to-metal seal assemblies 11. The glass-to-metal seal assembly 11 may provide a metallic body 12 having a first surface 22 and an opposing second surface 24. The metallic body 12 may be made of Kovar or other suitable metallic or alloy material conducive for forming a hermetic seal with glass. The metallic body 12 provides through holes 18 communicating between the first and second body surfaces 22 and 24. A portion of a pin 14 may be received through each through hole 18, while the remaining portion of each through hole 18 is substantially filled with sealing glass 20. The pin 14 may, too, be made of Kovar or other suitable metal center pin or conductor material. The sealing glass 20 may be made of borosilicate or other suitable glass preforms. The sealing glass 20 within each void 18 terminates at two opposing first and second glass surfaces 32 and 34 that may be spaced apart from and inward of the first and second body surfaces 22 and 24, respectively. Within the space defined by the periphery of the void 18 and the difference between the associated metallic body and glass surfaces 22 and 32 and 24 and 34 is a ceramic disc 16 with an opening to receive the pin 14. The ceramic washer/disc 16 may be made of aluminum oxide or other suitable ceramic material.

There are typically two types of glass to metal seals. One is a matched seal where the coefficient of thermal expansion of all of the components are closely matched, for example Kovar and Coining 7052 glass or equivalent. The hermetic bond between the glass and metal components relies primarily on an oxide to oxide bond at the interface. In this type of seal, the embodiment of this invention would utilize a ceramic disc 16 having a coefficient of thermal expansion matching that of the metal and glass and will provide a bond to the glass. This maintains a virtually stress-free condition as the glass cools and solidifies.

The second type of glass to metal seal is a compression seal. In this instance the coefficient of thermal expansion of the metal housing is greater than the coefficient of thermal expansion of the glass and center pin. For example, a cold rolled steel housing, a Coining 9010 glass or equivalent, and a 52-alloy pin. Upon the cooling of the softened glass, the outer housing contracts at a faster pace putting the glass and center pin in compression. The hermetic bond in this case is primarily mechanical. The embodiment of this invention for this type of hermetic seal would utilize a ceramic disc 16 that has a coefficient of thermal expansion that closely matches the glass. Upon cooling, the metal housing contracts faster than the ceramic disc 16, putting the ceramic in compression.

The present invention is made by selecting the appropriate metal for the housing and pin, and the appropriate glass that serves as the insulator and provides the hermetic seal, and the appropriate ceramic to cover the faces of the otherwise exposed glass. The metal components are sometimes treated with a chemical cleaning, outgassing, and controlled oxide growth to promote the sealing process.

The housing, glass and pin components 14 may be arranged to create an electrically isolated pin 14. The ceramic disc 16 may be placed on one or both sides of the glass 20. The components require the necessary tolerances to prevent any mechanical interference during assembly. The tolerances must also be tightly held to keep the components in close proximity to one another. The assembly 11 may be held in a refractory, high-temperature resistant fixture, such as graphite or carbon, so that the components are held in the appropriate orientation.

In certain embodiments, the fixture is then subjected to a temperature high enough to soften the glass and reduce the surface energy such that the glass wets the metal components and ceramic discs. Such high temperature may be provided through a furnace with proper temperature profile and atmosphere settings. An atmosphere of hydrogen and nitrogen with a controlled dew point is typically present during this process to keep the metal components from overly oxidizing. Upon the continuation of heat, the glass bonds to the oxides formed on the surface of the metal as well as the oxides present in the ceramic. Once adequate time has been allowed, the entire assembly is cooled at a controlled rate to solidify the glass creating a rigid assembly.

The ceramic disc 16 can be placed on one or both ends of the glass seal 20. It may also be possible to insert an additional ceramic disc 16 between two smaller glass preforms 20, as illustrated in FIG. 5, creating another interface which may aid in preventing crack propagation. The ceramic discs may be held within the thickness of the metal housing, or it may extend above that surface 22 or 24. Another configuration would have a thin ceramic plate 66 with multiple holes that fit over multiple pins in the glass-to-metal seal assembly 11, as illustrated in FIG. 4.

Once the complete glass-to-metal seal assembly 11 is formed and achieves the adequate hermeticity requirements, it can be used in its intended application. This may be a hermetic housing wherein microcircuit components are placed. The present invention can be used as a single or multi-pin hermetic connector for an electrical interface. The present invention can be used as an insulated feedthrough in harsh environments or applications (high temperature, cryogenic applications, high pressure, vacuum containment, corrosive liquids and gases, thermal cycling, mechanical shock and vibration, etc.) The end product that utilizes the present invention will be superior to conventional glass-to-metal seals. It will withstand mechanical, chemical and thermal stresses to a greater extend then conventional hermetic seals. The center pin 14 can also withstand radial bending better than a conventional glass seal. The ceramic disc 16 acts as a buffer to prevent the bending stresses from adversely affecting the glass seal.

A further benefit of the present invention is that it centers the pin within the seal better than a typical seal. This is because as the glass softens the pin 14 tends to shift radially, resulting in an off-center pin. The ceramic disc 16 mechanically holds the pin 14 centered in the seal and does not soften during the sealing process.

It should be understood, of course, that the foregoing relates to exemplary embodiments of the invention and that modifications may be made without departing from the spirit and scope of the invention as set forth in the following claims.

What is claimed is:

1. A glass-to-metal seal assembly for electrical components, comprising:
one or more glass-to-metal seals wherein a ceramic washer sandwiches the opposing ends of a glass portion of at least one glass-to-metal seal.

2. The glass-to-metal seal assembly of claim 1, wherein a coefficient of thermal expansion of each ceramic washer matches that of the glass portion.

3. The glass-to-metal seal assembly of claim 1, further comprising a metal body providing a through hole for each glass-to-metal seal, each through hole filled with the glass portion;
the metal body providing a first body surface and an opposing body second surface;
the glass portion terminating at opposing first and second glass surfaces; and
each first and second glass surface abuts a first ceramic surface of an operatively associated ceramic washer.

4. The glass-to-metal seal assembly of claim 3, wherein each ceramic washer provides a second ceramic surface opposite of said first ceramic surface, and wherein the second ceramic surface is disposed inward of an adjacent body surface.

5. The glass-to-metal seal assembly of claim 3, wherein each ceramic washer provides a second ceramic surface opposite of said first ceramic surface, and wherein the second ceramic surface is disposed flush with an adjacent body surface.

6. The glass-to-metal seal assembly of claim 3, wherein each ceramic washer provides a second ceramic surface opposite of said first ceramic surface, and wherein the second ceramic surface is disposed outward of an adjacent body surface.

7. The glass-to-metal seal assembly of claim 1, further comprising a third ceramic washer and a second glass portion is provided within the void.

8. The glass-to-metal seal assembly of claim 1, wherein each ceramic washer has an aperture for receiving an electrical component.

9. The glass-to-metal seal assembly of claim 3, wherein at least one ceramic washer has a plurality of apertures, each aperture for receiving an electrical component, and wherein said at least once ceramic washer abuts both the glass portion associated with each said electrical component and the associated body surface.
